(19) United States
(12) Patent Application Publication
(10) Pub. No.: US 2007/0069330 A1
(43) Pub. Date: Mar. 29, 2007

(54) Fuse structure for a semiconductor device

(76) Inventor: Jui-Meng Jao, Miaoli City (TW)

Correspondence Address: J.C. Patents, Suite 250, 4 Venture, Irvine, CA, 92618, US

(21) Appl. No.: 11/236,966

(22) Filed: Sep. 27, 2005

(51) Int. Cl. H01L 29/00

(52) U.S. Cl. 257/529

(57) ABSTRACT

A fuse structure on a peripheral region of a substrate, the fuse structure comprising a plurality of fuses disposed on a plane and parallel to each other, wherein each fuse has a melting block and the melting blocks are arranged in a staggered form. Because of the fuse structure with melting blocks disposed in a staggered arrangement, the pitch of the fuses is relatively small and the size of the semiconductor device is decreased.

### BACKGROUND OF THE INVENTION

1. Field of the Invention

This invention generally relates to a fuse structure for a semiconductor device, and more particularly to a fuse structure having melting blocks disposed in a stagger arrangement for a semiconductor device.

2. Description of Related Art

As the size of a semiconductor device becomes smaller, the semiconductor device is more seriously affected due to impurity or defects in itself. A defect of a single diode or transistor may cause the whole chip to fail. To solve this problem, some redundant circuits connected to fuses generally will be added into the circuit. When a defect is found in a circuit, the fuses can be used to disable the defected circuit and enable the redundant circuit. For memory devices, the defected cell can be replaced by a non-defected cell to its address. Another reason to use fuses in the integrated circuits is to permanently write the controlling bytes such as ID codes into the chip.

Generally, the fuses are made of polysilicon or metal materials. Laser fuses and electronic fuses are two major types of fuses based on how the fuses are blown. The laser fuses will be blown by the laser beam; and the electronic fuses will be blown by currents. The electronic fuses are generally applied to EEPROM devices, while the laser fuses are generally applied to DRAM devices.

Conventionally, the fuses are formed as wires and are made together with the interconnects by performing the semiconductor processes. With the decrease of the line width, for the fuses with even width, it is not easy to blow the fuses by using only one laser shot. Hence, by enlarging a portion of the fuse to increase the stress difference between the enlarged region and the normal region of the fuse, it is easier to blow the fuse around the enlarged region by only one laser shot. Nevertheless, in order to form the fuses with the enlarged portion, the pitch is increased dramatically since the enlarged portions of different fuses align to each other respectively.

### SUMMARY OF THE INVENTION

An object of the present invention is to provide a fuse structure with melting blocks disposed in a staggered arrangement capable of decreasing the pitch of the fuses and further decreasing the size of the semiconductor device.

The present invention provides a fuse structure on a peripheral region of a substrate, the fuse structure comprising a plurality of fuses disposed on a plane and parallel to each other, wherein each fuse has a melting block and the melting blocks are arranged in a staggered form.

In the present invention, the melting blocks respectively on every other fuse are aligned to each other. Also, the width of the melting block is larger than the width of the fuse. The pitch of the fuse is about 2.6˜7.6 μm and the width of each melting block is about 2.0˜4.0 μm. The fuse can be made of aluminum, copper or polysilicon.

The present invention further provides a fuse structure on a peripheral region of a substrate, the fuse structure comprising a plurality of fuses disposed on a plane and parallel to each other, wherein each fuse has a laser shot spot and the laser shot spots respectively on every other fuse are aligned to each other.

In the present invention, the width of the laser shot spot is larger than the width of the fuse. Furthermore, the pitch of the fuse is about 2.6˜7.6 μm and the width of each melting block is about 2.0˜4.0 μm. The fuse can be made of aluminum, copper or polysilicon.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a fuse structure in accordance with one preferred embodiment of the present invention.

### DESCRIPTION OF THE PREFERRED EMBODIMENTS

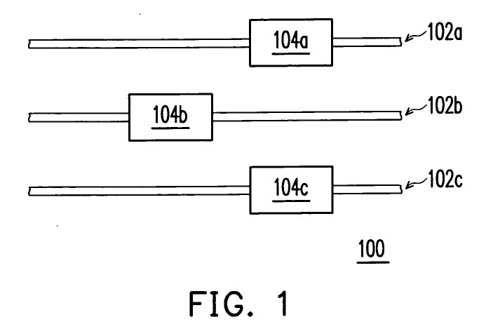

FIG. 1 is a schematic diagram of a fuse structure in accordance with one preferred embodiment of the present invention. As shown in FIG. 1, a fuse structure 100 is provided and the fuse structure 100 is located at a peripheral region of a substrate (not shown). The fuse structure 100 has several fuses including at least a fuse 102a, a fuse 102b and a fuse 102c. The fuses 102a, 102b and 102c are disposed on the same plane and are parallel to each other.

Notably, the fuses 102a, 102b and 102c have the melting blocks 104a, 104b and 104c respectively. The melting blocks 104a, 104b and 104c are used as the laser shot spots which the laser shoots on to blows the fuses. Since the width of the melting block is wider than that of the fuse, there exist stress difference between the fuse and the melting block. Therefore, once the laser shoots on the melting block of the fuse, the fuse is blown while the melting block is broken easily because of the stress difference.

However, the wider melting blocks will lead to the increasing of the pitch size of the fuse. In order to decreasing the pitch size while maintaining the benefit obtaining from enlarging the width of the melting block, the present invention provide a fuse structure with melting blocks disposed in a stagger arrangement. In one preferred embodiment, the melting blocks respectively on every other fuse are aligned to each other. That is, as shown in FIG. 1, the melting block 104a on the fuse 102a and the melting block 104c on the fuse 102c are aligned to each other, wherein the fuse 102b is located between the fuse 102a and the fuse 102c.

In one preferred embodiment, the fuses 102a, 102b and 102c are made of aluminum, copper or polysilicon. Furthermore, the width of each of the fuse is about 0.5˜4.0 μm and the width of each of the melting block is about 2.0˜4.0 μm. Also, the pitch of the fuses is about 2.6˜7.6 μm.

Furthermore, since the enlarged portion, the melting block, of the fuses are compactly and complementarily arranged, the pitch size of the fuse is relatively small. Also, in one preferred embodiment, because the melting blocks respectively on every other fuse are aligned to each other, the size of the melting block can be increased without increasing the pitch of the fuse and the size of the chip. Therefore, the cost for manufacturing the semiconductor device can be decreased.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A fuse structure comprising a plurality of fuses disposed on a plane and parallel to each other, wherein each fuse has a melting block and the melting blocks are arranged in a staggered form.

2. The fuse structure of claim 1, wherein the melting blocks respectively on every other fuse are aligned to each other.

3. The fuse structure of claim 1, wherein the width of the melting block is larger than the width of the fuse.

4. The fuse structure of claim 1, wherein the pitch of the fuse is about 2.6˜7.61 μm.

5. The fuse structure of claim 1, wherein the fuse is made of aluminum.

6. The fuse structure of claim 1, wherein the fuse is made of copper.

7. The fuse structure of claim 1, wherein the fuse is made of polysilicon.

8. The fuse structure of claim 1, wherein the width of each melting block is about 2.0˜4.0 μm.

9. The fuse structure of claim 1, wherein the fuse structure is located on a peripheral region of a substrate.

10. A fuse structure comprising a plurality of fuses disposed on a plane and parallel to each other, wherein each fuse has a laser shot spot and the laser shot spots respectively on every other fuse are aligned to each other.

11. The fuse structure of claim 10, wherein the width of the laser shot spot is larger than the width of the fuse.

12. The fuse structure of claim 10, wherein the pitch of the fuse is about 2.6˜7.6 μm.

13. The fuse structure of claim 10, wherein the fuse is made of aluminum.

14. The fuse structure of claim 10, wherein the fuse is made of copper.

15. The fuse structure of claim 10, wherein the fuse is made of polysilicon.

16. The fuse structure of claim 10, wherein the width of each laser shot spot is about 2.0˜4.0 μm.

17. The fuse structure of claim 10, wherein the fuse structure is located on a peripheral region of a substrate.
